(19) United States
(12) Patent Application Publication
(10) Pub. No.: US 2024/0387171 A1
(43) Pub. Date: Nov. 21, 2024

(54) STRUCTURE OF HIGH-RESISTIVITY SILICON-ON-INSULATOR EMBEDDED WITH CHARGE CAPTURE LAYER AND MANUFACTURE THEREOF

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Hongtao XU, Shanghai (CN); Ziwen WANG, Shanghai (CN); Meng CHEN, Shanghai (CN); Minghao LI, Shanghai (CN); Wei LI, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 18/660,322

(22) Filed: May 10, 2024

(30) Foreign Application Priority Data
May 19, 2023 (CN) 202310573286.1

(51) Int. Cl. H01L 21/02; H01L 21/762; H01L 21/763

(52) U.S. Cl. CPC H01L 21/02667; H01L 21/0242; H01L 21/02595; H01L 21/76243; H01L 21/763

(57) ABSTRACT

The present application provides a structure of HR-SOI embedded with a charge capture layer and manufacture thereof. The process for manufacturing a structure of HR-SOI embedded with a charge capture layer comprises: providing a first substrate, wherein the first substrate has a first surface to be subjected to a roughness treatment to form an uneven morphology on the first surface; forming a surface treatment layer, wherein the surface treatment layer has an uneven surface morphology; and forming a polysilicon layer on the surface treatment layer. By the roughness treatment to the first substrate, the first surface and the surface treatment layer both have uneven surface morphology, such that the formed polysilicon layer has stable orientation evolution and grain size, and an increased grain boundary density. Thereby a highly efficient charge trapping polysilicon film can be obtained.

### BACKGROUND OF THE INVENTION

### 1. Field of the Invention

The present application relates to a technical field of semiconductor manufacture, and more particularly to a structure and a manufacturing process of silicon-on-insulator.

### 2. Description of the Related Art

Currently, silicon-on-insulator (SOI) has been broadly applied in the fields of microelectronics, optics, and optoelectronics, and there are correspondently more challenges for materials. Because of the increasingly strict requirements for radio frequency front-end of smart devices in 5G, radio frequency SOI (RF-SOI) can be widely applied.

RF-SOI includes high-resistivity silicon-on-insulator (HR-SOI) and trap-rich high-resistivity silicon-on-insulator (TR-SOI). HR-SOI is similar to traditional SOI, but based on traditional SOI, a high-resistance silicon substrate is used to replace the original substrate to form HR-SOI and obtain well radio frequency performance. However, it is difficult to maintain high linearity at high frequencies. Regarding TR-SOI, it is based on HR-SOI to embed a polysilicon film between the insulating buried oxide layer (BOX) and the high-resistance silicon substrate as a carrier trap layer, which can effectively suppress surface parasitic capacitance (PSC) effect and improve the RF performance of the substrate. In the manufacture of TR-SOI, the preparation process of polysilicon film is crucial.

In the conventional preparation of a polysilicon film, atmospheric pressure chemical vapor deposition (APCVD) or low pressure chemical vapor deposition (LPCVD) are mainly applied with in-situ rapid thermal annealing to obtain polysilicon films with good particle quality and low stress. When a polysilicon film is deposited on the surface of a flat high-resistance silicon substrate, the polysilicon film will first show random crystal orientation and competitive growth, but then a preferential orientation phenomenon will gradually appear, causing the polysilicon film to grow columnarly in several fixed orientations. The grain morphology of each layer is fixed, the number of grain boundaries is constant, and the trap density remains unchanged. Thereby the grain boundary density of the polysilicon film is limited, and a highly efficient charge-trapping polysilicon film cannot be obtained.

To resolve the above problems, CN107533953A discloses that holes with 5 nm to 1000 nm are formed in the textured oxide layer, nitride or oxynitride layer to roughen the surface of the layer, and to obtain a high efficiency polysilicon film. However, for extremely thin oxide layers, thermal treatment under high temperature can cause pyrolysis of the oxide layer, which can easily lead to failure of polysilicon growth in some areas, such that additional processes are needed for roughness of the wafer surface.

### SUMMARY

The purpose of the present application is to provide a structure of HR-SOI embedded with a charge capture layer and manufacture thereof, which can increase the grain boundary density of a polysilicon film, thereby a highly efficient charge trapping polysilicon film can be obtained.

To solve the above mentioned problems, the present application provides a process for manufacturing a structure of HR-SOI embedded with a charge capture layer comprising:
providing a first substrate, wherein the first substrate has a first surface to be subjected to a roughness treatment to form an uneven morphology on the first surface;
forming a surface treatment layer, wherein the surface treatment layer has an uneven surface morphology, and
forming a polysilicon layer on the surface treatment layer.

### BRIEF DESCRIPTION OF THE DRAWINGS

FIG. 1 shows, in accordance with one embodiment of the present application, a process for manufacturing a structure of HR-SOI embedded with a charge capture layer.

FIG. 2 to FIG. 4 show, in accordance with one embodiment of the present application, the structural of each step in the process for manufacturing a structure of HR-SOI embedded with a charge capture layer.

### DETAILED DESCRIPTION OF THE EMBODIMENTS

The present application provides a process for manufacturing a structure of HR-SOI embedded with a charge capture layer comprising: providing a first substrate, wherein the first substrate has a first surface to be subjected to a roughness treatment to form an uneven morphology on the first surface; forming a surface treatment layer, wherein the surface treatment layer has an uneven surface morphology, and forming a polysilicon layer on the surface treatment layer.

In one embodiment, the roughness treatment comprises: roughing the first surface by a chemical vapor etching process to form an uneven morphology on the first surface.

In one embodiment, the roughness treatment comprises: loading the first substrate into a chemical vapor deposition reactor at a loading temperature; heating to a first temperature from the loading temperature to conduct a vapor etching to the first substrate; cooling; and outputting the first substrate from the reactor.

Further, while the first substrate is loaded into the chemical vapor deposition reactor, the loading temperature is 500° C.-800° C. and the atmosphere is hydrogen.

In one embodiment, the vapor etching is conducted with the following parameters. An atmosphere is a mixture of hydrogen and hydrogen chloride. The flow rate of hydrogen chloride is 0.1 slm-1 slm. The first temperature is less than 1000° C. The reaction time is 30 seconds (s)-400 s.

Further, in the cooling step, the atmosphere is transferred to hydrogen, the temperature is lowered to 500° C.-800° C., and the cooling rate is 1° C./min-10° C./min.

In one embodiment, the first surface is subjected to a surface treatment comprising:
cleaning the first surface to form an oxide layer; and
annealing the first substrate.

In one embodiment, the first surface is subjected to a surface treatment comprising:
cleaning the first surface to form an oxide layer;
nitriding the oxide layer to form a nitride layer or an oxynitride layer; and
annealing the first substrate.

In one embodiment, the process of forming the polysilicon layer comprises: conducting a chemical vapor deposition process to form a polysilicon film on the surface treatment layer.

In another aspect, the present application provides a structure of HR-SOI embedded with a charge capture layer, which is prepared by the above mentioned process. The HR-SOI embedded with a charge capture layer has a structure comprising a first substrate, a surface treatment layer and a polysilicon layer stacked in sequence. The first substrate has a first surface subjected to a roughness treatment. The surface treatment layer and the polysilicon layer are formed on the side of the first surface. The surface treatment layer and the first surface have a morphology identical to each other. The morphology is uneven morphology.

Comparing with conventional techniques, the present application has the following advantages.

The present application provides a structure of HR-SOI embedded with a charge capture layer and manufacture thereof. The process for manufacturing a structure of HR-SOI embedded with a charge capture layer comprises: providing a first substrate, wherein the first substrate has a first surface to be subjected to a roughness treatment to form an uneven morphology on the first surface; forming a surface treatment layer, wherein the surface treatment layer has an uneven surface morphology; and forming a polysilicon layer on the surface treatment layer. By the roughness treatment to the first surface, the first surface and the surface treatment layer both have uneven surface morphology, such that the formed polysilicon film layer has stable orientation evolution and grain size, and an increased grain boundary density. Thereby a highly efficient charge trapping polysilicon film can be obtained.

### Examples

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Example embodiments will now be described more fully with reference to the accompanying drawings. Noted that accompanying drawing is simplified and applies non-accurately ratio for the purpose of clear and convenient illustration of the example of the present invention.

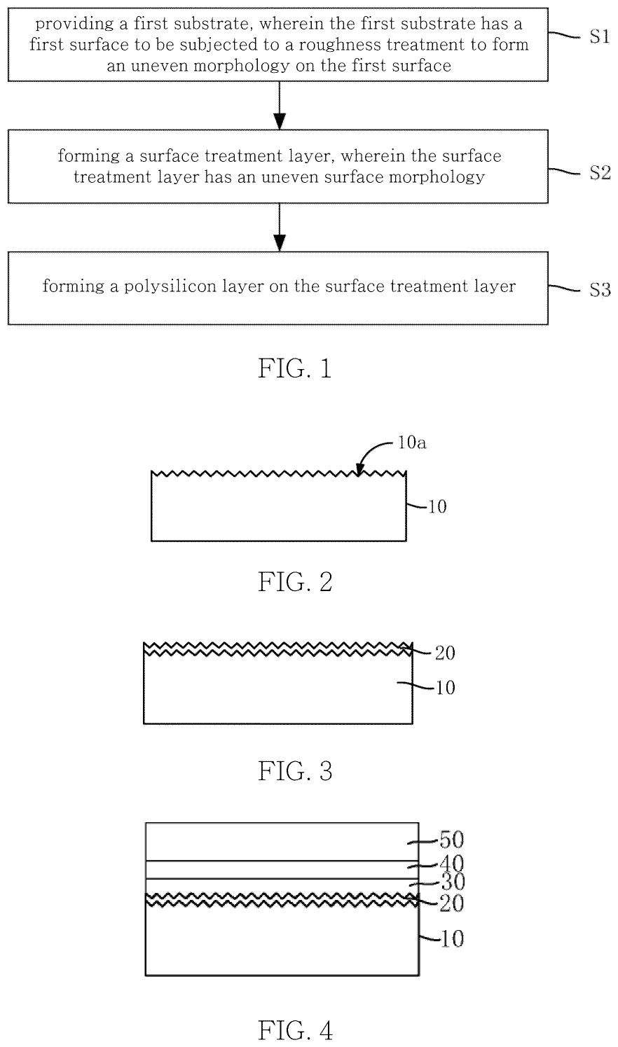

FIG. 1 shows, in accordance with one embodiment of the present application, a process for manufacturing a structure of HR-SOI embedded with a charge capture layer. As shown in FIG. 1, the process comprises the following steps:
Step S1: providing a first substrate, wherein the first substrate has a first surface to be subjected to a roughness treatment to form an uneven morphology on the first surface,
Step S2: forming a surface treatment layer, wherein the surface treatment layer has an uneven surface morphology, and
Step S3: forming a polysilicon layer on the surface treatment layer.

With reference to FIGS. 2-4, the process of the present application will be described in detail.

As shown in FIG. 2, the Step S1 is firstly conducted. A first substrate 10 is provided. The first substrate 10 has a first surface 10a, and a roughness treatment is conducted to the first surface 10a to form an uneven morphology.

In this step, the first substrate 10 can be a monocrystalline silicon semiconductor wafer with high resistivity. In one embodiment, the resistivity of the first substrate 10 can be 1 kΩ-10 kΩ. The first substrate 10 has a front surface 10a and a back surface opposite to the first surface 10a.

Chemical vapor etching process is used as the roughness treatment to the first surface 10a to form an uneven morphology on the first surface 10a. In one embodiment, the first substrate 10 is loaded into a CVD reactor at a loading temperature. The loading temperature can be 500° C.-800° C., preferably 650° C. The atmosphere is hydrogen. Then, the loading temperature is increased to a first temperature to conduct a vapor etching to the first substrate 10. At this stage of vapor etching, the atmosphere is transferred to a gaseous mixture of hydrogen and hydrogen chloride (HCl), the gas flow rate of HCl can be 0.1 slm-1 slm, the gas flow rate of hydrogen can be 40 slm-80 slm, causing the ratio of HCl to hydrogen in the CVD reactor can be 1:100-1:20. The first temperature can be less than 1000° C., preferably 900° C.-950° C. The reaction time can be 30 s-400 s, preferably 120 s-180 s. The heating rate can be 0.5° C./min-20° C./min. After completion of vapor etching, the atmosphere is transferred to hydrogen. The temperature is cooled down to 500° C.-800° C., preferably 650° C. The cooling rate is 1° C./min-10° C./min, preferably 3° C./min-5° C./min. Subsequently, the first substrate 10 is taken out from the CVD reactor. In this embodiment, the vapor etching is conducted to the first surface 10a by using the gaseous mixture containing HCl, such that the first surface is regularly roughened.

As shown in FIG. 3, the step S2 is conducted to form a surface treatment layer on the first surface, and the surface treatment layer also has an uneven morphology on its surface. The surface treatment layer can be an oxide layer, a nitride layer or an oxynitride layer.

When the surface treatment layer 20 is an oxide layer, this step includes: cleaning the first surface 10a to form an oxide layer. In one embodiment, the first substrate 10 is washed by a first solution at a first washing temperature, then by a second solution at a second washing temperature. The first substrate 10 is washed by deionized water at the first washing temperature. The first substrate 10 is finally washed by the first solution at the first washing temperature to grow the surface treatment layer, i.e. the oxide layer. In one embodiment, the oxide layer has a thickness of about 1.5 nm. The morphology of the oxide layer is identical to that of the first surface 10a, i.e. an uneven morphology. The first solution can be ozone water with the ozone (O3) concentration of 10 ppm-50 ppm. The second solution can be RCA-SC1 solution. The second solution can have a ratio of ammonia:hydrogen peroxide of 1:1-1:3. The first washing temperature can be room temperature such as 22° C.-27° C. The second washing temperature can be 35° C.-70° C.

When the surface treatment layer 20 is a nitride layer or an oxynitride layer, this step includes the following.

Firstly, the first surface 10a is cleaned to form an oxide layer. In one embodiment, the first substrate 10 is washed by a first solution at a first washing temperature, then by a second solution at a second washing temperature. The first substrate 10 is washed by deionized water at the first washing temperature. The first substrate 10 is finally washed by the first solution at the first washing temperature to grow an oxide layer. In one embodiment, the oxide layer has a thickness of about 1.5 nm. The morphology of the oxide layer is identical to that of the first surface 10a, i.e. an uneven morphology. The first solution can be ozone water with the ozone (O3) concentration of 10 ppm-50 ppm. The second solution can be RCA-SC1 solution. The second solution can have a ratio of ammonia:hydrogen peroxide of 1:1-1:3. The first washing temperature can be room temperature such as 22° C.-27° C. The second washing temperature can be 35° C.-70° C.

Subsequently, nitriding of the oxide layer is conducted to form a nitride layer or an oxynitride layer. In one embodiment, the first substrate 10 is loaded into the CVD reactor. The loading temperature can be 500° C.-800° C., preferably 650° C. The atmosphere is nitrogen. Then, the loading temperature is increased to a second temperature to conduct the nitriding to the oxide layer. At the nitriding stage, the atmosphere is transferred to nitrogen atmosphere, the gas flow rate of nitrogen can be 40 slm-80 slm. The second temperature can be 850° C.-1000° C., preferably 900° C.-950° C. The reaction time can be 10 s-120 s, preferably 30 s-60 s. The morphology of the surface treatment layer is identical to that of the first surface, i.e. an uneven morphology.

As shown in FIG. 4, the step S3 is conducted to form the polysilicon film layer 30 on the surface treatment layer 20. Because of the uneven morphology of the surface treatment layer 20, the polysilicon film 30 intends to have stable orientation evolution and grain size during the formation of the polysilicon film layer 30. Thereby the polysilicon film layer 30 has a higher grain boundary density. As such, a highly efficient charge trapping polysilicon film can be obtained.

This step specifically includes forming the polysilicon layer 30 on the surface treatment layer 20 by chemical vapor deposition process. In one embodiment, after the completion of the nitriding treatment, the temperature of the CVD reactor is adjusted to a third temperature to conduct atmospheric pressure chemical vapor deposition (APCVD). The atmosphere is transferred to a gaseous mixture of hydrogen and trichlorosilane (TCS). The gas flow rate of TCS can be 10 slm-20 slm, preferably 12 slm-16 slm. The gas flow rate of hydrogen can be 40 slm-80 slm, preferably 60 slm. The third temperature can be 850° C.-1000° C., preferably 900° C.-950° C. The reaction time of APCVD can be adjusted depending on the thickness requirement for the polysilicon film layer 30.

Subsequently, the annealing treatment is conducted to the first substrate 10. In one embodiment, in-situ rapid thermal annealing (RTA) to the first substrate 10 is initiated by heating to the annealing temperature and transferring the atmosphere to hydrogen atmosphere. The gas flow rate of hydrogen can be 40 slm-80 slm, preferably 60 slm. The annealing temperature can be 1000° C.-1200° C., preferably, 1100° C.-1150° C.

A second substrate 50 is provided. In one embodiment, an insulating buried oxide layer 40 is then formed by a routine method, namely, an insulating buried oxide layer 40 is formed on the polysilicon film layer 30. In another embodiment, an insulating buried oxide layer 40 is formed on the second substrate 50. In another embodiment, an insulating buried oxide layer 40 with a partial thickness is formed on the polysilicon film layer 30, and the insulating buried oxide layer 40 with the remaining thickness is formed on the second substrate 50. The first substrate 10 is bonded with the second substrate 50 by a routine method to obtain the structure of HR-SOI embedded with a charge capture layer. The processes of forming the insulating buried oxide layer 40 and bonding the first substrate 10 with the second substrate 50 will not be limited herein, and can be the conventional processes known by a person having ordinary skills in the art.

Continue to referring FIG. 2 to FIG. 4, this embodiment also describes a structure of HR-SOI embedded with a charge capture layer comprising a first substrate 10, a surface treatment layer 20, a polysilicon layer 30, an insulating buried oxide layer 40 and second substrate 50, stacked in sequence. The first substrate 10 can be a monocrystalline silicon semiconductor wafer with high resistivity. In one embodiment, the resistivity of the first substrate 10 can be 1 kΩ-10 kΩ. The first substrate 10 has a first surface 10a, and the surface treatment layer 20 and the polysilicon layer 30 are located on the side of the first surface. The first surface 10a is subjected to a roughness treatment to have an uneven morphology. The surface treatment layer 20 can be an oxide layer, a nitride layer or an oxynitride layer, and has the morphology identical to the first surface 10a, i.e. the uneven morphology. The second substrate 50 can be a monocrystalline silicon semiconductor wafer.

According to the above, the present application provides a structure of HR-SOI embedded with a charge capture layer and manufacture thereof. The process for manufacturing a structure of HR-SOI embedded with a charge capture layer comprises: providing a first substrate, wherein the first substrate has a first surface to be subjected to a roughness treatment to form an uneven morphology on the first surface; forming a surface treatment layer, wherein the surface treatment layer has an uneven surface morphology; and forming a polysilicon layer on the surface treatment layer. By the roughness treatment to the first substrate, the first surface of the first substrate and the surface treatment layer both have uneven surface morphologies, such that the formed polysilicon film layer has stable orientation evolution and grain size, making the polysilicon film layer have a higher grain boundary density. Thereby a highly efficient charge trapping polysilicon film can be obtained.

Unless the context clearly indicates otherwise, use of the words such as “first”, “second”, and “third” merely distinguish one component, element, step and the like from another component, element, step and the like, but does not indicate any sequence of the components, elements, steps and the like.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. A process for manufacturing a structure of high-resistivity silicon-on-insulator (HR-SOI) embedded with a charge capture layer comprising:
providing a first substrate, wherein the first substrate has a first surface to be subjected to a roughness treatment to form an uneven morphology on the first surface;
forming a surface treatment layer, wherein the surface treatment layer has an uneven surface morphology, and
forming a polysilicon layer on the surface treatment layer.

2. The process of claim 1, wherein the roughness treatment comprises: roughing the first surface by a chemical vapor etching process to form an uneven morphology on the first surface.

3. The process of claim 2, wherein the roughness treatment comprises:
loading the first substrate into a chemical vapor deposition reactor at a loading temperature;
heating from the loading temperature to a first temperature to conduct a vapor etching to the first substrate;
cooling, and
outputting the first substrate from the reactor.

4. The process of claim 3, wherein the loading temperature is 500° C.-800° C. with an atmosphere of hydrogen.

5. The process of claim 3, wherein the vapor etching is conducted under an atmosphere of a mixture of hydrogen and hydrogen chloride, a flow rate of hydrogen chloride of 0.1 slm-1 slm, the first temperature of less than 1000° C., and a reaction time of 30 s-400 s.

6. The process of claim 3, wherein in the cooling step, an atmosphere is transferred to hydrogen, the temperature is lowered to 500° C.-800° C. with a cooling rate of 1° C./min-10° C./min.

7. The process of claim 1, wherein the first surface is subjected to a surface treatment comprising: cleaning the first surface to form an oxide layer.

8. The process of claim 1, wherein the first surface is subjected to a surface treatment comprising:
cleaning the first surface to form an oxide layer, and
nitriding the oxide layer to form a nitride layer or an oxynitride layer.

9. The process of claim 1, wherein the polysilicon layer is formed on the surface treatment layer by chemical vapor deposition process.

10. A high-resistivity silicon-on-insulator (HR-SOI) embedded with a charge capture layer characterized by, having a structure comprising a first substrate, a surface treatment layer and a polysilicon layer stacked in sequence,
wherein the first substrate has a first surface subjected to a roughness treatment, the surface treatment layer and the polysilicon layer are formed on the side of the first surface, and the surface treatment layer and the first surface have a morphology identical to each other, and the morphology is uneven morphology, and
wherein the structure is prepared by a process of claim 1.
